(19) United States
(12) Patent Application Publication
(10) Pub. No.: US 2016/0360619 A1
(43) Pub. Date: Dec. 8, 2016

(54) PASSIVE DEVICE

(71) Applicant: YAGEO CORPORATION, Kaohsiung City (TW)

(72) Inventors: Sheng-Li HSIAO, Kaohsiung City (TW); Yung-Han Liu, Kaohsiung City (TW); Shih-Hsin CHANG, Kaohsiung City (TW); Ping-Chuen KUO, Kaohsiung City (TW); Shu-Fang CHEN, Kaohsiung City (TW); Ching-Chang LIN, Kaohsiung City (TW)

(73) Assignee: YAGEO CORPORATION, Kaohsiung City (TW)

(21) Appl. No.: 14/954,273

(22) Filed: Nov. 30, 2015

(30) Foreign Application Priority Data
Jun. 2, 2015 (TW) 104208728

(51) Int. Cl. H05K 1/18; H05K 1/11

(52) U.S. Cl. CPC H05K 1/18; H05K 1/113

(57) ABSTRACT

A passive device includes a substrate that has opposite first and second surfaces, an electrical connecting unit, a first passive unit, and a second passive unit. The electrical connecting unit includes a first pad formed on the first surface and a second pad formed on the second surface and is electrically connected to the first pad. The first passive unit is formed on the first surface and electrically connected to the first pad. The second passive unit is formed on the second surface and includes two separated electrode layers electrically insulated from the electrical connecting unit, and an insulator layer interconnecting the electrode layers.

### CROSS-REFERENCE TO RELATED APPLICATION

This application claims priority of Taiwanese Application No. 104208728, filed on Jun. 2, 2015.

### FIELD

The disclosure relates to a passive device, more particularly to a passive device with an electrical connecting unit.

### BACKGROUND

In view of the trend toward requiring an electronic device to be thin and small, a passive device (e.g., a resistor chip, a capacitor chip, and an inductor chip) disposed on a printed circuit board (PCB) in an electronic product is designed to be small in size.

Conventional passive devices are connected and stacked in series or in parallel and then mounted on a PCB, or directly embedded in the PCB. However, the applicability of the passive device is limited since the series-parallel structure is determined during its design phase, and electrical connections cannot be easily adjusted. In addition, damaged passive devices embedded in the PCB cannot be replaced individually, but instead require a complete replacement of the PCB.

Furthermore, when the conventional passive devices are mounted on the PCB, PCB integration is reduced due to glue or solder creep.

Therefore, there is a need in the art for a passive device that has an improved stacking structure and occupies a small area on a PCB, so as to improve the integration of the PCB.

### SUMMARY

Therefore, an object of the disclosure is to provide a passive device that can alleviate at least one of the drawbacks of the prior arts.

According to the disclosure, the passive device includes a substrate, an electrical connecting unit, a first passive unit, and a second passive unit.

The substrate has opposite first and second surfaces.

The electrical connecting unit includes a first pad that is formed on the first surface, and a second pad that is formed on the second surface and that is electrically connected to the first pad.

The first passive unit is formed on the first surface of the substrate and is electrically connected to the first pad of the electrical connecting unit.

The second passive unit is formed on the second surface of the substrate and includes two separated electrode layers that are electrically insulated from the electrical connecting unit, and a resistor layer interconnecting the electrode layers.

### BRIEF DESCRIPTION OF THE DRAWINGS

Other features and advantages of the disclosure will become apparent in the following detailed description of the embodiments with reference to the accompanying drawings, of which:

FIG. 1 is a schematic view illustrating a first embodiment of a passive device according to the disclosure;

FIG. 2 is a bottom view of the first embodiment; and

FIG. 3 is a schematic view illustrating a second embodiment of a passive device according to the disclosure.

### DETAILED DESCRIPTION

Before the disclosure is described in greater detail, it should be noted that like elements are denoted by the same reference numerals throughout the disclosure.

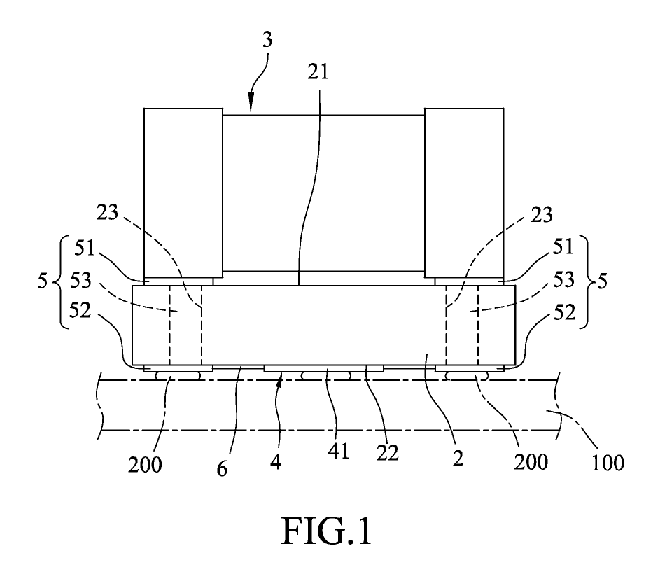

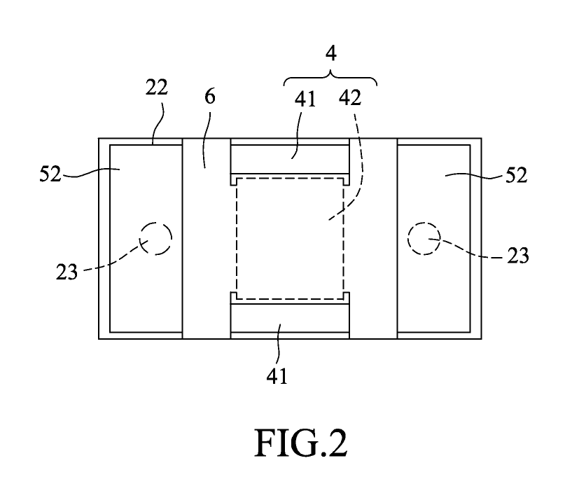

Referring to FIGS. 1 and 2, the first embodiment of a passive device according to the present disclosure includes a substrate 2, two electrical connecting units 5, a first passive unit 3, a second passive unit 4, and a protecting layer 6.

The substrate 2 has opposite first and second surfaces 21, 22.

The electrical connecting units 5 are separated from each other. Each of the electrical connecting units 5 includes a first pad 51 and a second pad 52. Each of the first pads 51 is formed on the first surface 21 of the substrate 2. Each of the second pads 52 is formed on the second surface 22 of the substrate 2 and is electrically connected to a respective one of the first pads 51.

The substrate 2 is defined with two through holes 23 that are spaced from each other. Each of the through holes 23 extends through the substrate 2 from the first surface 21 to the second surface 22. Each of the electrical connecting units 5 further has a wire 53 that passes through a respective one of the through holes 23 in the substrate 2 to electrically connect the first pad 51 and the second pad 52.

The number of electrical connecting units 5 may vary based on actual requirements.

The first passive unit 3 is formed on the first surface 21 of the substrate 2 and is electrically connected to the first pads 51 of the electrical connecting units 5.

The second passive unit 4 is formed on the second surface 22 of the substrate 2 and is insulated from the electrical connecting units 5. In this embodiment, the second passive unit 4 includes two separated electrode layers 41 that are electrically insulated from the electrical connecting units 5, and a resistor layer 42 that interconnects the electrode layers 41.

The protecting layer 6 covers the resistor layer 42 and exposes the electrode layers 41 and the second pads 52. In the first embodiment, the protecting layer 6 further covers the second surface 22 that is exposed from the second pads 52 and the second passive unit 4. The protecting layer 6 prevents the resistor layer 42 from oxidation or pollution.

It should be noted that the substrate 2 may be made from any suitable material, e.g., ceramic. The first passive unit 3 may be a chip capacitor or a chip conductor. In this embodiment, the first passive unit 3 is a chip capacitor, and the second passive unit 4 is a chip resistor.

In the first embodiment, the through holes 23 are formed using laser drilling techniques. The first and second pads 51, 52 of the electrical connecting units 5, the electrode layers 41, and the resistor layer 42 are formed on the substrate 2using printing techniques. The wires 53 of the electrical connecting units 5 are formed using filling techniques. For example, a conductive paste (e.g., silver paste or silver-palladium paste) is filled into the through holes 23 to form the wires 53. Alternatively, the wires 53 may be made by forming a seed layer (e.g., a copper layer) on a hole-defining surface that defines a respective one of the through holes 23 using a sputter technique, and forming on the seed layer a conductive metal layer (e.g., Cu, Ni, Pd, or Au layer) using an electro-plating technique or a chemical-plating technique.

The first passive unit 3 electrically connected to the first pads 51 is electrically connected to the second pads 52 through the wires 53.

The second pads 52 of the electrical connecting units 5 and the electrode layers 42 of the second passive unit 4 may be mounted on a PCB with solder materials 200, so that the first passive unit 3 and the second passive unit 4 that are electrically insulated from each other and that are respectively disposed on two opposite surfaces 21, 22 of the substrate 2 can be simultaneously and electrically connected to the PCB. Furthermore, the first passive unit 3 and the second passive unit 4 can be independently controlled by the PCB. With such structural design, the area of the PCB 100 occupied by the passive device can be reduced and the integration of the PCB 100 can be improved.

Furthermore, the solder materials 200 disposed on the electrode layers 42 and the second pads 52 of the electrical connecting units 5 can prevent solder creep, so that the volume utilization efficiency of the PCB 100 may be enhanced.

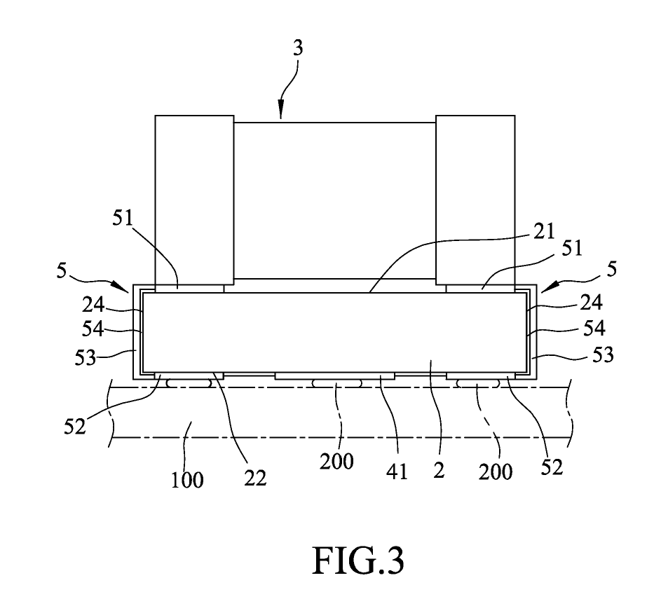

Referring to FIG. 3, a second embodiment of the passive device of the present disclosure is similar to the first embodiment. The second embodiment differs from the first embodiment in that the substrate 2 further includes two opposite side surfaces 24 that interconnect the first and second surfaces 21, 22, and is not formed with the through holes 23. In each electrical connecting unit 5, the wire 53 is formed on a respective side surface 24, so as to electrically connect the first pad 51 and the second pad 52.

In addition, each of the electrical connecting units further includes a conducting layer 54 that is sandwiched between the wire 53 and the respective one of the side surfaces 24. The conducting layers 54 of the electrical connecting units 5 are formed by sputtering an alloy material, e.g., nichrome, on the side surfaces 24. The wires 53 of the electrical connecting units 5 are formed by plating a conducting material, e.g., copper, nickel, or tin, on the conducting layers 54, so as to electrically and respectively connect the first pads 51 to the second pads 52. With the conducting layers 54, the wires 53 can be firmly formed on the side surfaces 24 by the plating technique.

In view of the forgoing, with the electrical connecting units 5, the first passive unit 3 and the second passive unit 4 can be controlled and operated individually, which facilitates subsequent connection in series or in parallel with other passive units. Moreover, mounting the first and second passive units 3, 4 on the single substrate 2 could improve integration of the PCB.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A passive device, comprising:
a substrate having opposite first and second surfaces;
an electrical connecting unit including a first pad that is formed on said first surface, a second pad that is formed on said second surface and that is electrically connected to the first pad;
a first passive unit that is formed on the first surface of said substrate and that is electrically connected to said first pad of said electrical connecting unit; and
a second passive unit that is formed on said second surface of said substrate and that includes two separated electrode layers electrically insulated from the electrical connecting unit, and a resistor layer interconnecting said electrode layers.

2. The passive device of claim 1, wherein said substrate is defined with a through hole extending through said substrate from said first surface to said second surface, said electrical connecting unit further including a wire that passes through said through hole in said substrate to electrically connect said first pad and said second pad.

3. The passive device of claim 1, wherein said substrate further has a side surface that interconnects said first and second surfaces, said electrical connecting unit further including a wire being formed on said side surface to electrically connect said first pad and said second pad.

4. The passive device of claim 3, wherein said electrical connecting unit further includes a conducting layer that is sandwiched between said wire and said side surface.

5. The passive device of claim 1, wherein said first passive unit is a chip capacitor or a chip inductor, and said second passive unit is a chip resistor.

6. The passive device of claim 1, further comprises a protecting layer that covers said resistor layer and exposes said electrode layers and said second pads.

7. The passive device of claim 1, wherein said passive device includes two of said electrical connecting units that are separated from each other.
